(19) United States
(12) Patent Application Publication
(10) Pub. No.: US 2015/0380161 A1
(43) Pub. Date: Dec. 31, 2015

(54) MULTILAYER CERAMIC ELECTRONIC COMPONENT TO BE EMBEDDED IN BOARD, MANUFACTURING METHOD THEREOF AND PRINTED CIRCUIT BOARD HAVING THE SAME EMBEDDED THEREIN

(71) Applicant: SAMSUNG ELECTRO-MECHANICS CO., LTD., SUWON-SI (KR)

(72) Inventors: Jong Bong LIM, Suwon-si (KR); Hai Joon LEE, Suwon-si (KR); Doo Young KIM, Suwon-si (KR); Chang Hoon KIM, Suwon-si (KR)

(73) Assignee: SAMSUNG ELECTRO-MECHANICS CO., LTD.

(21) Appl. No.: 14/484,566

(22) Filed: Sep. 12, 2014

(30) Foreign Application Priority Data
Jun. 26, 2014 (KR) 10-2014-0078656

(51) Int. Cl. H01G 4/012; C23C 14/34; H01G 4/12; H01G 4/248; H01G 4/30; H01G 4/008

(52) U.S. Cl. CPC H01G 4/012; H01G 4/30; H01G 4/008; H01G 4/1227; H01G 4/248; C23C 14/34

(57) ABSTRACT

A multilayer ceramic electronic component may include: a ceramic body including dielectric layers and having first and second main surfaces opposing each other, first and second side surfaces opposing each other, and first and second end surfaces opposing each other; first and second internal electrodes alternately exposed to the end surfaces with the dielectric layer interposed therebetween; and first and second external electrodes including connection portions disposed on the end surfaces and connected to the internal electrodes and band portions extended to portions of the main surfaces. The connection portions and the band portions are formed of a conductive thin film, and a width of the band portion may be greater than a distance between an end of the first internal electrode and the second end surface or a distance between an end of the second internal electrode and the first end surface.

### CROSS-REFERENCE TO RELATED APPLICATION

This application claims the benefit of Korean Patent Application No. 10-2014-0078656 filed on Jun. 26, 2014, with the Korean Intellectual Property Office, the disclosure of which is incorporated herein by reference.

### BACKGROUND

The present disclosure relates to a multilayer ceramic electronic component to be embedded in a board, a manufacturing method thereof, and a printed circuit board having the same embedded therein.

As electronic circuits have become highly integrated, amounting space for electronic components mounted on a printed circuit board has become insufficient. In order to solve this problem, ongoing efforts have been made to have components installed within a board.

In general, a multilayer ceramic electronic component includes a plurality of dielectric layers formed of a ceramic material and internal electrodes inserted between the plurality of dielectric layers. The multilayer ceramic electronic component has high capacitance and this capacitive component is disposed in the printed circuit board, whereby a mounting space of a highly integrated printed circuit board may be secured.

### Related Art Document

(Patent Document 1) Korean Patent Laid-Open Publication No. 2011-0122008

### SUMMARY

An exemplary embodiment in the present disclosure may provide a multilayer ceramic electronic component capable of being embedded in a printed circuit board to secure a mounting space, a manufacturing method thereof, and a printed circuit board having the same embedded therein.

According to an exemplary embodiment in the present disclosure, a multilayer ceramic electronic component to be embedded in a board may include: a ceramic body including dielectric layers and having first and second main surfaces opposing each other, first and second side surfaces opposing each other, and first and second end surfaces opposing each other; first and second internal electrodes alternately exposed to the first and second end surfaces of the ceramic body, with at least one of the dielectric layers interposed therebetween; and first and second external electrodes including connection portions disposed on the first and second end surfaces of the ceramic body and connected to the first and second internal electrodes and band portions extended to at least a portion of the first and second main surfaces of the ceramic body, wherein the connection portions and the band portions of the first and second external electrodes are formed of a conductive thin film, and a width of the band portion is greater than a distance between an end of the first internal electrode and the second end surface or a distance between an end of the second internal electrode and the first end surface.

The conductive thin film may have a thickness of 1 nm to 10 μm and may be formed by performing a thin film forming process such as a sputtering process, a chemical vapor deposition (CVD), a physical vapor deposition (PVD), a spin coating process, an atomic layer deposition (ALD), a pulsed laser deposition (PLD), and the like, or an electroless plating process.

### BRIEF DESCRIPTION OF DRAWINGS

The above and other aspects, features and advantages will be more clearly understood from the following detailed description taken in conjunction with the accompanying drawings, in which:

FIG. 1 is a perspective view of a multilayer ceramic electronic component to be embedded in a board according to an exemplary embodiment in the present disclosure;

FIG. 2 is a cross-sectional view taken along line I-I′ of FIG. 1;

FIG. 3 is a cross-sectional view of a multilayer ceramic electronic component to be embedded in a board according to an exemplary embodiment in the present disclosure; and

FIG. 4 is a cross-sectional view of a printed circuit board having a multilayer ceramic electronic component embedded therein according to an exemplary embodiment in the present disclosure.

### DETAILED DESCRIPTION

Exemplary embodiments in the present disclosure will now be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements maybe exaggerated for clarity, and the same reference numerals will be used throughout to designate the same or like elements.

### Multilayer Ceramic Electronic Component to be Embedded in Board

Hereinafter, a multilayer ceramic electronic component to be embedded in a board according to an exemplary embodiment in the present disclosure will be described. Particularly, a multilayer ceramic capacitor to be embedded in a board will be described. However, the present disclosure is not limited thereto.

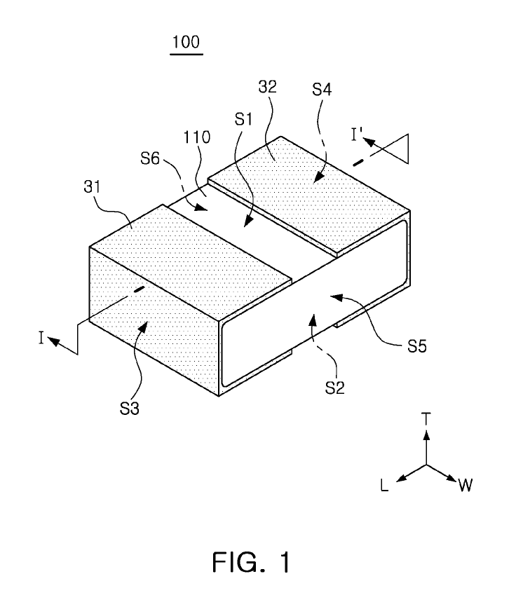

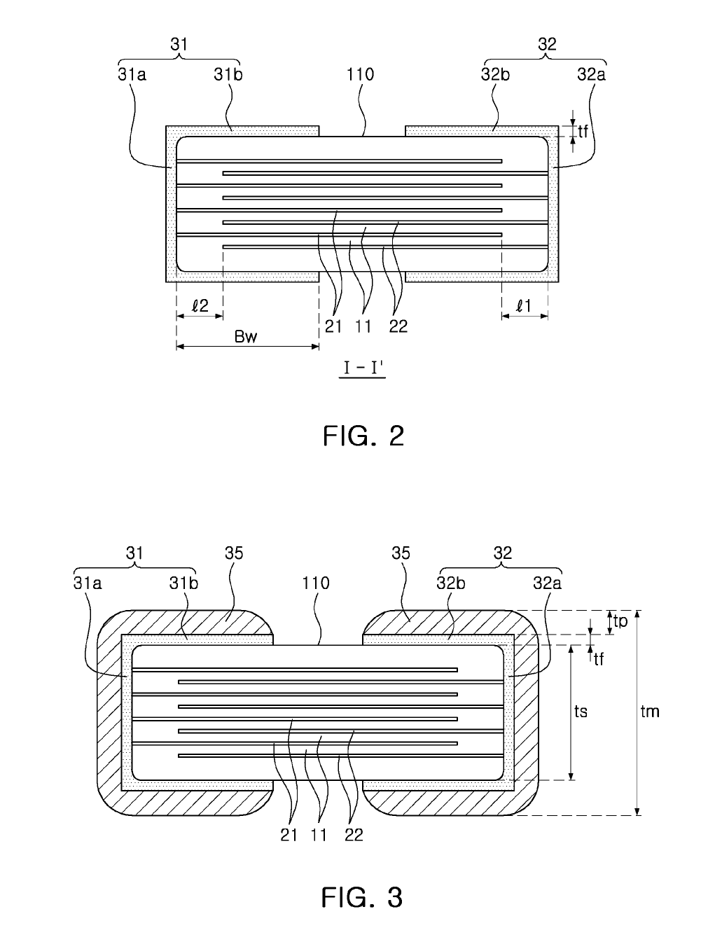

FIG. 1 is a perspective view of a multilayer ceramic electronic component to be embedded in a board according to an exemplary embodiment in the present disclosure; and FIG. 2 is a cross-sectional view taken along line I-I′ of FIG. 1.

Referring to FIG. 1, a multilayer ceramic electronic component 100 to be embedded in a board according to an exemplary embodiment in the present disclosure may include a ceramic body 110, first and second external electrodes 31 and 32 disposed on outer surfaces of the ceramic body 110.

In the embedded multilayer ceramic electronic component 100 according to the exemplary embodiment in the present disclosure, a ‘length direction’ refers to an ‘L’ direction of FIG. 1, a ‘width direction’ refers to a ‘W’ direction of FIG. 1, and a ‘thickness direction’ refers to a ‘T’ direction of FIG. 1.

The ceramic body 110 may have first and second main surfaces S1 and S2 opposing each other in the thickness T direction, first and second side surfaces S5 and S6 opposing each other in the width W direction, and first and second end surfaces S3 and S4 opposing each other in the length L direction.

The first and second external electrodes 31 and 32 may be disposed on the first and second end surfaces S3 and S4 of the ceramic body 110 and may be extended to portions of the first and second main surfaces S1 and S2. The first and second external electrodes 31 and 32 according to the exemplary embodiment in the present disclosure may include a conductive thin film.

Referring to FIG. 2, the ceramic body 110 may include dielectric layers 11 and first and second internal electrodes 21 and 22 disposed to face each other with at least one of the dielectric layers 11 interposed therebetween.

The ceramic body 110 may be formed by stacking a plurality of dielectric layers 11 in the thickness T direction and then sintering the plurality of dielectric layers 11. A shape and a dimension of the ceramic body 110 and the number of stacked dielectric layers 11 are not limited to those illustrated in the present embodiment.

The plurality of dielectric layers 11 constituting the ceramic body 110 may be in a sintered state. Adjacent dielectric layers 11 may be integrated with each other so that boundaries therebetween are not readily apparent without using a scanning electron microscope (SEM).

A raw material forming the dielectric layers 11 is not particularly limited as long as sufficient capacitance may be obtained, but may be, for example, a barium titanate (BaTiO₃) powder.

As the material forming the dielectric layers 11, various ceramic additives, organic solvents, plasticizers, binders, dispersing agents, and the like, may be added to a powder such as a barium titanate (BaTiO₃) powder, and the like.

The first and second internal electrodes 21 and 22, a pair of electrodes having different polarities, may be alternately exposed to the first and second end surfaces S3 and S4 of the ceramic body 110, and may be electrically insulated from each other by the dielectric layers 11 interposed therebetween.

The first and second internal electrodes 21 and 22 may be alternately exposed to the first and second end surfaces S3 and S4 of the ceramic body 110 and may be connected to the first and second external electrodes 31 and 32 disposed on the first and second end surfaces S3 and S4 of the ceramic body 110, respectively.

The width of the first and second internal electrodes 21 and 22 may be determined depending on use thereof. For example, considering the size of the ceramic body 110, the width of the first and second internal electrodes may be formed to satisfy a range of 0.2 μm to 1.0 μm, but is not limited thereto.

The first and second internal electrodes 21 and 22 may contain a conductive metal such as nickel. (Ni), copper (Cu), palladium (Pd), silver (Ag), lead (Pb), platinum. (Pt), or alloys thereof.

The first and second external electrodes 31 and 32 may include connection portions 31a and 32a disposed on the first and second end surfaces S3 and S4 of the ceramic body 110 and connected to the first and second internal electrodes 21 and 22, respectively, and band portions 31b and 32b extended to portions of the first and second main surfaces S1 and S2 of the ceramic body 110.

In the exemplary embodiment in the present disclosure, the first and second external electrodes 31 and 32 including the connection portions 31a and 32a and the band portions 31b and 32b may be formed of a conductive thin film.

When the external electrodes are formed according to the related art, a dipping method using a paste containing a conductive metal has usually been used.

In order to connect the external electrodes of the embedded multilayer ceramic capacitor to external wirings through vias, band portions of the external electrodes are required to have a predetermined width or more. However, in the case of using the existing dipping method, when the band portions having a predetermined width or more are formed, the band portions may be formed to be extremely thick due to interfacial tension of the paste.

When the thickness of the external electrodes is increased, the thickness of the ceramic body is relatively reduced by the increased thickness of the external electrodes. However, since the embedded multilayer ceramic electronic component is thinner than a non-embedded multilayer ceramic electronic component, the ceramic body of the embedded component becomes significantly thin, thereby leading to damage due to a reduction in strength thereof.

Accordingly, in the exemplary embodiment in the present disclosure, the first and second external electrodes 31 and 32 including the connection portions 31a and 32a and the band portions 31b and 32b may be formed of a conductive thin film, whereby the thickness of the external electrodes maybe reduced.

The conductive thin film may be formed by performing a thin film forming process such as a sputtering process, a chemical vapor deposition (CVD), a physical vapor deposition (PVD), a spin coating process, an atomic layer deposition (ALD), a pulsed laser deposition (PLD), and the like, or an electroless plating process.

The first and second external electrodes 31 and 32 formed of the conductive thin film through the sputtering process, and the like, according to the exemplary embodiment in the present disclosure may be formed to include the band portions having a predetermined width or more so as to connect the external electrodes to the external wirings through vias, while having a uniform and relatively reduced thickness.

The width (BW) of the band portion 31b or 32b may be greater than a distance l1 between an end of the first internal electrode 21 and the second end surface S4 or a distance l2 between an end of the second internal electrode 22 and the first end surface S3. When the width (BW) of the band portion 31b or 32b is greater than l1 or l2, defects that may occur at the time of via processing for connection with the external wirings may be prevented.

For example, the width (BW) of the band portion 31b or 32b may correspond to 25% or more of the length of the ceramic body 110. When the width (BW) of the band portion 31b or 32b corresponds to less than 25% of the length of the ceramic body 110, the probability of defects may be increased at the time of via processing for connection with the external wirings.

As the width (BW) of the band portion 31b or 32b is increased, the via processing for connection with the external wirings may be favorably performed and ESL may be reduced. Thus, the width (BW) of the band portions 31b and 32b may be formed to be sufficiently increased as long as short-circuits between the first and second external electrodes 31 and 32 do not occur.

Meanwhile, not only the band portions 31b and 32b but also the connection portions 31a and 32a, of the first and second external electrodes 31 and 32, may be formed of the conductive thin film, such that a sintering process of the external electrodes may be omitted and the manufacturing process may be simplified. In addition, since all of the connection portions 31a and 32a and the band portions 31b and 32b are formed of the conductive thin film, connection of the connection portions 31a and 32a and the band portions 31b and 32b may be firmly secured, and thus, a plating solution may be prevented from being permeated.

The conductive thin film may have a thickness (tf) of 1 nm to 10 μm. The conductive thin film is formed to be thin within the above range, such that the thickness of the external electrodes may be reduced, and the thickness of the ceramic body may be increased by the reduced thickness of the external electrodes, thereby improving strength.

In the case in which the thickness of the conductive thin film is less than 1 nm, it is difficult to form the conductive thin film to have a uniform thickness, and a discontinuous portion may be formed, and thus, adhesion strength with a plating layer formed on the conductive thin film may deteriorate. In the case in which the thickness of the conductive thin film is greater than 10 μm, time required to form the conductive thin film may be unnecessarily increased and the thickness of the external electrodes may be increased.

In addition, the external electrodes formed by the existing dipping method may have a large thickness deviation due to the interfacial tension of the paste. However, the conductive thin film according to the exemplary embodiment in the present disclosure may be formed to have a uniform thickness by reducing a thickness deviation of the external electrodes using the sputtering method or the like.

The conductive thin film may be formed of a conductive metal, the same as that of the first and second internal electrodes 21 and 22. For example, the conductive metal may be capper (Cu), nickel (Ni) palladium (Pd) , platinum (Pt), gold (Au) silver (Aq), Iron (Fe), titanium (Ti), carbon (C), or alloys thereof, but is not limited thereto.

Meanwhile, the conductive thin film may not contain a glass component.

The external electrodes formed by the existing dipping method contain the glass component in order to improve densification and facilitate a sintering process. However, since the conductive thin film according to the exemplary embodiment in the present disclosure does not require the sintering process of the external electrodes, the conductive thin film may not contain the glass component.

The conductive thin film according to the exemplary embodiment in the present disclosure may be formed of only the conductive metal without the glass component, but is not limited thereto.

FIG. 3 is a cross-sectional view of a multilayer ceramic electronic component to be embedded in a board according to another exemplary embodiment in the present disclosure.

Referring to FIG. 3, a multilayer ceramic electronic component according to another exemplary embodiment in the present disclosure may further include a plating layer 35 formed on the first and second external electrodes 31 and 32.

The plating layer 35 may be formed of a conductive metal. For example, the conductive metal may be copper (Cu), silver (Ag), nickel (Ni), tin (Sn), or alloys thereof, but is not limited thereto.

When the thickness of the conductive thin film is tf and the thickness of the plating layer 35 is tp, 1.5≦tp/tf≦10000 may be satisfied.

When the thickness tf of the conductive thin film is extremely thick or the thickness tp of the plating layer 35 is extremely thin, and tp/tf is less than 1.5, the plating layer may not have the minimum thickness of 5 μm. When the thickness tf of the conductive thin film is extremely thin or the thickness tp of the plating layer 35 is extremely thick, and tp/tf is greater than 10000, the thickness of the entire chip may be increased such that it may exceed a thickness required to be embedded, or the thickness of the ceramic body may be relatively reduced, whereby strength may be lowered.

The total thickness tm of the embedded multilayer ceramic capacitor 100 including the first and second external electrodes 31 and 32 and the plating layer 35 may be 300 μm or less.

In order to embed the multilayer ceramic capacitor 100 in a printed circuit board, the total thickness tm of the multilayer ceramic capacitor 100 may satisfy 300 μm or less.

Here, the thickness ts of the ceramic body 110 may correspond to 70% or more of the total thickness tm of the multilayer ceramic capacitor including the first and second external electrodes 31 and 32.

When the thickness ts of the ceramic body 110 corresponds to less than 70% of the total thickness tm of the multilayer ceramic capacitor, the strength thereof may be decreased, resulting in defects such as damage, and the like.

### Method of Manufacturing Multilayer Ceramic Electronic Component to be Embedded in Board

In the method of manufacturing a multilayer ceramic electronic component to be embedded in a board according to an exemplary embodiment in the present disclosure, a slurry containing a powder such as a barium titanate (BaTiO₃) powder, and the like, may be applied to carrier films and dried to thereby prepare a plurality of ceramic sheets.

The ceramic sheets may be formed by preparing the slurry by mixing a ceramic powder such as a barium titanate (BaTiO₃) powder, or the like with a binder, a solvent, and the like and forming the slurry as sheets having a thickness of several μm by a doctor blade method.

Then, a conductive paste containing a conductive metal may be prepared. The conductive metal may be nickel (Ni), copper (Cu), palladium (Pd), silver Ag), lead Pb), platinum (Pt), or alloys thereof, and may have an average particle size of 0.1 μm to 0.2 μm. The conductive paste for internal electrodes may contain 40 to 50 wt % of the conductive metal.

The conductive paste for internal electrodes may be applied to the ceramic sheets by a printing method, or the like, to form internal electrode patterns. The printing method of the conductive paste may be a screen printing method, a gravure printing method, or the like, but is not limited thereto.

200 to 300 ceramic sheets having the internal electrode patterns printed thereon may be stacked to form a laminate including the first and second internal electrodes 21 and 22 formed therein.

Then, the laminate may be compressed and sintered to form the ceramic body 110.

Next, the first and second external electrodes 31 and 32 formed of the conductive thin film may be formed on outer surfaces of the ceramic body 110.

The first and second external electrodes 31 and 32 may include the connection portions 31a and 32a disposed on the first and second end surfaces S3 and S4 of the ceramic body 110 and connected to the first and second internal electrodes 21 and 22, respectively, and the band portions 31b and 32b extended to at least a portion of the first and second main surfaces S1 and S2 of the ceramic body 110.

The first and second external electrodes 31 and 32 formed of the conductive thin film may be formed by performing a thin film forming process such as a sputtering process, a chemical vapor deposition (CVD), a physical vapor deposition (PVD), a spin coating process, an atomic layer deposition (ALD), a pulsed laser deposition (PLD), and the like, or an electroless plating process.

According to the exemplary embodiment in the present disclosure, since the first and second external electrodes 31 and 32 are formed of the conductive thin film through the thin film forming processes such as the sputtering process, and the like, or the electroless plating process, the band portions may be formed to have a predetermined width or more so as to connect the external electrodes to the external wirings through the vias, while the external electrodes may be formed to have a uniform and relatively reduced thickness.

Meanwhile, according to the exemplary embodiment in the present disclosure, since not only the band portions 31b and 32b but also the connection portions 31a and 32a, of the first and second external electrodes 31 and 32, are formed of the conductive thin film through the thin film forming process such as the sputtering process, and the like, or the electroless plating process, a separate sintering process of the external electrodes may be omitted and the manufacturing process may be simplified.

In addition, since all of the connection portions 31a and 32a and the band portions 31b and 32b are formed of the conductive thin film, connection of the connection portions 31a and 32a and the band portions 31b and 32b may be firmly secured, whereby a plating solution may be prevented from being permeated.

Further, the external electrodes formed by the existing dipping method contain a glass component in order to improve densification and facilitate a sintering process. However, in the case in which the first and second external electrodes 31 and 32 are formed by the thin film forming process such as the sputtering process, and the like, or the electroless plating process as in the exemplary embodiment in the present disclosure, the sintering process of the external electrodes is not required, and thus, the glass component may not be contained.

Then, the plating layer 35 may be further formed on the first and second external electrodes 31 and 32.

A description of features the same as those of the embedded multilayer ceramic electronic component according to the previous exemplary embodiment in the present disclosure will be omitted herein.

### Printed Circuit Board Having Multilayer Ceramic Electronic Component Embedded Therein

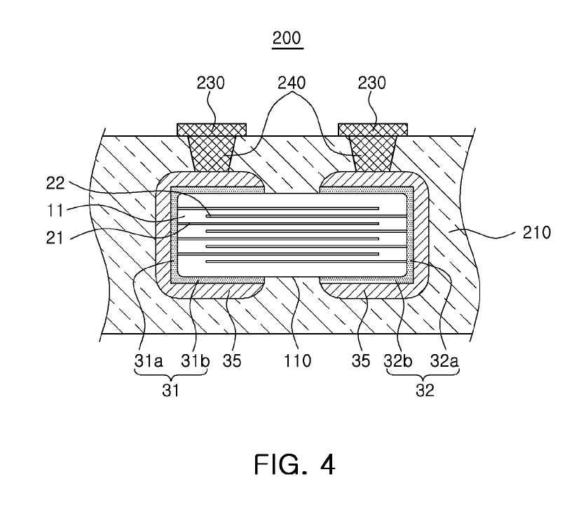

FIG. 4 is a cross-sectional view of a printed circuit board having a multilayer ceramic electronic component embedded therein according to an exemplary embodiment in the present disclosure.

Referring to FIG. 4, a printed circuit board 200 having a multilayer ceramic electronic component embedded therein according to an exemplary embodiment in the present disclosure may include an insulating layer 210, a conductive pattern 230 disposed on one surface of the insulating layer 210; and a multilayer ceramic electronic component embedded in the insulating layer 210.

The embedded multilayer ceramic electronic component may include a ceramic body 110 including dielectric layers 11, first and second internal electrodes 21 and 22 alternately exposed to the first and second end surfaces S3 and S4 of the ceramic body 110 with at least one of the dielectric layers 11 interposed therebetween, and first and second external electrodes 31 and 32 including connection portions 31a and 32a disposed on the first and second end surfaces S3 and S4 of the ceramic body 110 and connected to the first and second internal electrodes 21 and 22, respectively, and band portions 31b and 32b extended to at least a portion of first and second main surfaces S1 and S2 of the ceramic body 110, wherein the connection portions 31a and 32a and the band portions 31b and 32b of the first and second external electrodes are formed of a conductive thin film, and the width of the band portion 31b or 32b is greater than a distance l1 between an end of the first internal electrode 21 and the second end surface S4 or a distance l2 between an end of the second internal electrode 22 and the first end surface S3.

The printed circuit board 200 may further include vias 240 in the insulating layer 210, the vias connecting the band portions 31b and 32b of the external electrodes of the embedded multilayer ceramic electronic component to the conductive pattern 230 insulating layer.

The external wirings of the printed circuit board 200 and the embedded multilayer ceramic electronic component may be electrically connected to each other through the vias 240.

Here, in order to prevent defects at the time of via processing, the width (BW) of the band portion 31b or 32b may be greater than l1 or l2.

Meanwhile, in order to embed the multilayer ceramic electronic component in the insulating layer 210, the total thickness tm of the embedded multilayer ceramic electronic component may be 300 μm or less.

Since the embedded multilayer ceramic electronic component is formed to be thinner than a non-embedded multilayer ceramic electronic component, in the case in which the thickness of the external electrodes is increased, the ceramic body of the embedded component becomes significantly thin, thereby leading to damage due to a reduction in strength thereof. Therefore, the external electrodes of the embedded multilayer ceramic electronic component are required to be thin.

However, according to the related art, when the width of the band portions is increased for via connection, the thickness of the external electrodes has been increased.

Accordingly, in the embedded multilayer ceramic electronic component according to the exemplary embodiment in the present disclosure, the first and second external electrodes 31 and 32 are formed of the conductive thin film by the sputtering process, and the like, such that the thickness of the external electrodes may be reduced while the band portions are formed to have a predetermined width or more for via connection, whereby the strength of the chip may be improved.

A description of features the same as those of the embedded multilayer ceramic electronic component according to the previous exemplary embodiment in the present disclosure will be omitted.

As set forth above, according to exemplary embodiments in the present disclosure, the external electrodes are formed of a thin film through a deposition process, such that the thickness of the external electrodes may be reduced while allowing the band portions of the external electrodes to have a predetermined width or more so as to connect the external electrodes to the external wirings through the vias.

While exemplary embodiments have been shown and described above, it will be apparent to those skilled in the art that modifications and variations could be made without departing from the scope of the invention as defined by the appended claims.

What is claimed is:

1. A multilayer ceramic electronic component to be embedded in a board, comprising:
a ceramic body including dielectric layers and having first and second main surfaces opposing each other, first and second side surfaces opposing each other, and first and second end surfaces opposing each other;
first and second internal electrodes alternately exposed to the first and second end surfaces of the ceramic body, with at least one of the dielectric layers interposed therebetween; and
first and second external electrodes including connection portions disposed on the first and second end surfaces of the ceramic body and connected to the first and second internal electrodes and band portions extended to at least a portion of the first and second main surfaces of the ceramic body,
wherein the connection portions and the band portions of the first and second external electrodes are formed of a conductive thin film, and
a width of the band portion is greater than a distance between an end of the first internal electrode and the second end surface or a distance between an end of the second internal electrode and the first end surface.

2. The multilayer ceramic electronic component of claim 1, wherein the conductive thin film has a thickness of 1 nm to 10 μm.

3. The multilayer ceramic electronic component of claim 1, wherein the conductive thin film contains at least one selected from the group consisting of copper (Cu), nickel (Ni), palladium (Pd), plantinum (Pt), gold (Au), silver (Ag), Iron (Fe) titanium (Ti) and carbon (C).

4. The multilayer ceramic electronic component of claim 1, wherein the conductive thin film does not contain a glass component.

5. The multilayer ceramic electronic component of claim 1, wherein the width of the band portion corresponds to 25% or more of a length of the ceramic body.

6. The multilayer ceramic electronic component of claim 1, further comprising a plating layer disposed on the first and second external electrodes.

7. The multilayer ceramic electronic component of claim 6, wherein when a thickness of the conductive thin film is tf and a thickness of the plating layer is tp, 1.5≦tp/tf≦10000 is satisfied.

8. The multilayer ceramic electronic component of claim 6, wherein the ceramic body has a thickness corresponding to 70% or more of a total thickness of the multilayer ceramic electronic component including the first and second external electrodes and the plating layer.

9. The multilayer ceramic electronic component of claim 6, wherein the multilayer ceramic electronic component including the first and second external electrodes and the plating layer has a total thickness of 300 μm or less.

10. A method of manufacturing a multilayer ceramic electronic component to be embedded in a board, the method comprising:
forming a laminate including first and second internal electrodes formed therein;
forming a ceramic body by sintering the laminate; and
forming first and second external electrodes including connection portions formed on first and second end surfaces of the ceramic body and connected to the first and second internal electrodes and band portions extended to at least a portion of first and second main surfaces of the ceramic body,
wherein in the forming of the first and second external electrodes, a conductive thin film is formed by performing a sputtering process or an electroless plating process.

11. The method of claim 10, wherein the conductive thin film has a thickness of 1 nm to 10 μm.

12. The method of claim 10, wherein the forming of the first and second external electrodes is performed without a sintering process.

13. The method of claim 10, wherein a width of the band portion corresponds to 25% or more of a length of the ceramic body.

14. The method of claim 10, further comprising forming a plating layer on the first and second external electrodes.

15. A printed circuit board having a multilayer ceramic electronic component embedded therein, the printed circuit board comprising:
an insulating layer;
a conductive pattern disposed on at least one surface of the insulating layer; and
a multilayer ceramic electronic component embedded in the insulating layer,
wherein the embedded multilayer ceramic electronic component includes:
a ceramic body including dielectric layers and having first and second main surfaces opposing each other, first and second side surfaces opposing each other, and first and second end surfaces opposing each other;
first and second internal electrodes alternately exposed to the first and second end surfaces of the ceramic body, with at least one of the dielectric layers interposed therebetween; and
first and second external electrodes including connection portions disposed on the first and second end surfaces of the ceramic body and connected to the first and second internal electrodes and band portions extended to at least a portion of the first and second main surfaces of the ceramic body,
the connection portions and the band portions of the first and second external electrodes are formed of a conductive thin film, and
a width of the band portion is greater than a distance between an end of the first internal electrode and the second end surface or a distance between an end of the second internal electrode and the first end surface.

16. The printed circuit board of claim 15, further comprising vias disposed in the insulating layer to connect the band portions to the conductive pattern.
